(19) United States
(12) Patent Application Publication
(10) Pub. No.: US 2017/0033076 A1
(43) Pub. Date: Feb. 2, 2017

(54) PRODUCTION METHOD FOR SEMICONDUCTOR PACKAGE

(71) Applicant: NITTO DENKO CORPORATION, Ibaraki-shi, Osaka (JP)

(72) Inventors: Kosuke Morita, Ibaraki-shi, Osaka (JP); Tsuyoshi Ishizaka, Ibaraki-shi, Osaka (JP); Jun Ishii, Ibaraki-shi, Osaka (JP); Goji Shiga, Ibaraki-shi, Osaka (JP); Chie Iino, Ibaraki-shi, Osaka (JP)

(21) Appl. No.: 15/106,439

(22) PCT Filed: Dec. 22, 2014
(86) PCT No.: PCT/JP2014/083903

§ 371 Date: Jun. 20, 2016

(30) Foreign Application Priority Data
Dec. 26, 2013 (JP) 2013-270095

(51) Int. Cl. H01L 23/00; H01L 21/52; H01L 25/00; H01L 21/78

(52) U.S. Cl. CPC H01L 24/83; H01L 21/78; H01L 21/7806; H01L 21/52; H01L 25/50; H01L 2224/83091; H01L 2224/83097; H01L 2224/83203

(57) ABSTRACT

Provided is a production method for a semiconductor package making it possible to embed, in its irregularities, a thermosetting resin sheet satisfactorily. The method is a production method, for a semiconductor package, including the step of forming a sealed body by pressurizing a stacked body which includes: a chip-temporarily-fixed body comprising a supporting plate, a temporarily-fixing material stacked over the supporting plate, and a semiconductor chip fixed temporarily over the temporarily-fixing material; a thermosetting resin sheet arranged over the chip-temporarily-fixed body; and a separator having a tensile storage elastic modulus of 200 MPa or less at 90° C. and arranged over the thermosetting resin sheet; the sealed body including the semiconductor chip and the thermosetting resin sheet covering the semiconductor chip.

### TECHNICAL FIELD

The present invention relates to a production method for a semiconductor package.

### BACKGROUND ART

As a production method for a semiconductor package, a method has been hitherto known in which semiconductor chips fixed onto, for example, a temporarily-fixing material are sealed with a sealing resin. As such a sealing resin, for example, a thermosetting resin sheet is known (see, for example, Patent Document 1).

### PRIOR ART DOCUMENT

### Patent Document

Patent Document 1: JP-A-2006-19714

### SUMMARY OF THE INVENTION

### Problems to be Solved by the Invention

The thermosetting resin sheet cannot follow irregularities made of or formed by the temporarily-fixing material and the semiconductor chips on the temporarily-fixing material, so that voids may be generated. The voids cause the semiconductor package to be lowered in reliability.

An object of the present invention is to solve the problem and provide a production method for a semiconductor package making it possible to embed, in its irregularities, a thermosetting resin sheet satisfactorily.

### Means for Solving the Problems

A first aspect of the present invention relates to a production method for a semiconductor package, the method comprising:

a step of forming a sealed body by pressurizing a stacked body which comprises: a chip-temporarily-fixed body comprising a supporting plate, a temporarily-fixing material stacked over the supporting plate, and a semiconductor chip fixed temporarily over the temporarily-fixing material; a thermosetting resin sheet arranged over the chip-temporarily-fixed body; and a separator having a tensile storage elastic modulus of 200 MPa or less at 90° C. and arranged over the thermosetting resin sheet,

the sealed body comprising the semiconductor chip and the thermosetting resin sheet covering the semiconductor chip.

In the first aspect of the invention, the separator is used, which has a low tensile storage elastic modulus at 90° C., this temperature being near an ordinary temperature at which semiconductor chips are each covered with any thermosetting resin sheet. For this reason, the separator can be deformed in conformity with the deformation of the thermosetting resin sheet following the irregularities, so that the thermosetting resin sheet can be satisfactorily embedded in the irregularities.

In the first aspect of the invention, pressure is applied across the separator to the thermosetting resin sheet and the others. Thus, when the stacked body is hot-pressed in a parallel-flat-plate manner, the thermosetting resin sheet can be prevented from adhering to a press machine therefor.

In the step of forming the sealed body, it is preferred that the stacked body is pressurized while heated. This case makes it possible to form the sealed body easily.

In the step of forming the sealed body, it is preferred that the stacked body is pressurized at a temperature of 70° C. to 100° C. This case makes it possible to deform the separator easily in conformity with the deformation of the thermosetting resin sheet.

A second aspect of the present invention relates to a production method for a semiconductor package, the method comprising:

a step of forming a sealed structure body by pressurizing a stacked structure body which comprises: a chip mounted wafer comprising a semiconductor wafer and a semiconductor chip mounted over the semiconductor wafer; a thermosetting resin sheet arranged over the chip mounted wafer; and a separator having a tensile storage elastic modulus of 200 MPa or less at 90° C. and arranged over the thermosetting resin sheet,

the sealed structure body comprising the semiconductor wafer, the semiconductor chip mounted over the semiconductor wafer, and the thermosetting resin sheet covering the semiconductor chip.

A third aspect of the present invention relates to a production method for a semiconductor package, the method comprising:

a step of forming a sealed product by pressurizing a stacked product which comprises: a chip mounted substrate comprising a substrate and a semiconductor chip mounted over the substrate; a thermosetting resin sheet arranged over the chip mounted substrate; and a separator having a tensile storage elastic modulus of 200 MPa or less at 90° C. and arranged over the thermosetting resin sheet,

the sealed product comprising the substrate, the semiconductor chip mounted over the substrate, and the thermosetting resin sheet covering the semiconductor chip.

### Effect of the Invention

According to the semiconductor package production method of each of the first, second and third aspects of the present invention, the separator can be deformed in conformity with the deformation of the thermosetting resin sheet; thus, the thermosetting resin sheet can be satisfactorily embedded in the irregularities.

### BRIEF DESCRIPTION OF THE DRAWINGS

FIG. 1 is a sectional view that schematically illustrates a state of a stacked body arranged between a lower heating plate and an upper heating plate.

FIG. 2 is a sectional view that schematically illustrates a situation that the stacked body is hot-pressed in a parallel-flat-plate manner.

FIG. 3 is a sectional view that schematically illustrates a situation that a separator is peeled off from a sealed body obtained by the hot pressing.

FIG. 4 is a schematic sectional view of the sealed body after its temporarily-fixing material is peeled off.

FIG. 5 is a sectional view that schematically illustrates a situation that a resin region of a cured body is ground.

FIG. 6 is a sectional view that schematically illustrates a situation that a buffer coat film is formed on the cured body.

FIG. 7 is a sectional view that schematically illustrates a situation that openings are made in the buffer coat film in the state of arranging a mask on the buffer coat film.

FIG. 8 is a sectional view that schematically illustrates a situation after the mask has been removed.

FIG. 9 is a sectional view that schematically illustrates a situation that a resist is formed on a seed layer.

FIG. 10 is a sectional view that schematically illustrates a situation that a plating pattern is formed on the seed layer.

FIG. 11 is a sectional view that schematically illustrates a situation that re-interconnections are completed.

FIG. 12 is a sectional view that schematically illustrates a situation that a protective film is formed on the re-interconnections.

FIG. 13 is a sectional view that schematically illustrates a situation that openings are made in the protective film.

FIG. 14 is a sectional view that schematically illustrates a situation that electrodes are formed on the re-interconnections.

FIG. 15 is a sectional view that schematically illustrates a situation that bumps are formed on the electrodes.

FIG. 16 is a schematic sectional view of semiconductor packages yielded by making the re-interconnection body into individual pieces.

FIG. 17 is a sectional view that schematically illustrates a state of a stacked structure body arranged between a lower heating plate and an upper heating plate.

FIG. 18 is a sectional view that schematically illustrates a situation that the stacked structure body is hot-pressed in a parallel-flat-plate manner.

FIG. 19 is a sectional view that schematically illustrates a situation that a separator is peeled off from a sealed structure body obtained by the hot pressing.

FIG. 20 is a sectional view that schematically illustrates a situation that a surface of a cured structure body that is opposite to a wafer surface of the body is ground.

FIG. 21 is a sectional view that schematically illustrates a situation that a ground surface is formed by grinding the wafer surface.

FIG. 22 is a schematic sectional view of a re-interconnection structure body obtained by forming a re-interconnection layer on the ground surface.

FIG. 23 is a schematic sectional view of semiconductor packages obtained by making the re-interconnection structure body into individual pieces.

FIG. 24 is a schematic sectional view illustrating an example of a vacuum heating joint apparatus used in a production method of Embodiment 3.

FIG. 25 is a sectional view that schematically illustrates a situation that a stacked product is arranged on a substrate putting stand.

FIG. 26 is a sectional view that schematically illustrates a situation that a chamber is formed which is airtightly surrounded by an upper heating plate, an upper frame member and a lower plate member.

FIG. 27 is a sectional view that schematically illustrates a situation that an airtightly closed space, for holding a chip mounted substrate and a thermosetting resin sheet, is formed by covering the chip mounted substrate and the thermosetting resin sheet with a separator.

FIG. 28 is a sectional view that schematically illustrates a situation that a sealed product is formed, using a difference in pressure between the inside and the outside of the airtightly closed space.

FIG. 29 is a sectional view that schematically illustrates a situation that the sealed product is flattened.

### MODE FOR CARRYING OUT THE INVENTION

Hereinafter, the present invention will be described in detail by way of embodiments thereof. However, the invention is not limited only to these embodiments.

### Embodiment 1

A method of Embodiment 1 makes it possible to produce a fan-out type wafer level package (WLP).

As illustrated in FIG. 1, a stacked body 1 has a chip temporarily-fixed body 11, a thermosetting resin sheet 12 arranged on the chip temporarily-fixed body 11, and a separator 13 arranged on the thermosetting resin sheet 12. The stacked body 1 is arranged between a lower heating plate 41 and an upper heating plate 42.

The chip temporarily-fixed body 11 has a supporting plate 11a, a temporarily-fixing material 11b stacked on the supporting plate 11a, and semiconductor chips 14 temporarily fixed on the temporarily-fixing material 11b.

The material of the supporting plate 11a is not particularly limited, and examples thereof include metal materials such as SUS, and plastic materials such as polyimide, polyamideimide, polyetheretherketone, and polyethersulfone.

The temporarily-fixing material 11b is not particularly limited. There is usually used a thermally peelable adhesive such as a thermally foaming adhesive since the adhesive can easily be peeled off.

The semiconductor chips 14 each have a circuit-forming surface on which electrode pads 14a are formed. The chip temporarily-fixed body 11 is in a state that the circuit-forming surfaces of the semiconductor chips 14 contact the temporarily-fixing material 11b.

The thermosetting resin sheet 12 will be later described in detail.

The tensile storage elastic modulus of the separator 13 at 90° C. is 200 MPa or less, and is preferably less than 200 MPa, more preferably 150 MPa or less. Since the elastic modulus is 200 MPa or less, the thermosetting resin sheet can be satisfactorily embedded in the irregularities. The lower limit of the tensile storage elastic modulus of the separator 13 at 90° C. is not particularly limited. The tensile storage elastic modulus of the separator 13 at 90° C. is, for example, 1 MPa or more. When the elastic modulus is 1 MPa or more, the separator 13 can easily be cut and worked to be excellent in practicability.

The tensile storage elastic modulus at 90° C. is measurable by a method described in the item “EXAMPLES”.

As the separator 13, for example, a polyolefin film is preferably usable, examples of the polyolefin including polyethylene, polypropylene and ethylene propylene copolymer.

The thickness of the separator 13 is not particularly limited, and is preferably 35 μm or more, more preferably 50 μm or more. Moreover, the thickness of the separator 13 is preferably 200 μm or less, more preferably 100 μm or less. When the thickness is 200 μm or less, the separator 13 is easily deformed in conformity with the deformation of the thermosetting resin sheet 12.

As illustrated in FIG. 2, the lower heating plate 41 and the upper heating plate 42 are used to hot-press the stacked body 1 in a parallel-flat-plate manner to form a sealed body 51.

The temperature for the hot pressing is preferably 70° C. or higher, more preferably 80° C. or higher, even more preferably 85° C. or higher. When the temperature is 70° C. or higher, the thermosetting resin sheet 12 can be melted and caused to flow so that the sheet 12 can be satisfactorily embedded in the irregularities. The temperature for the hot pressing is preferably 100° C. or lower, more preferably 95° C. or lower. When the temperature is 100° C. or lower, the shaped body can be restrained from being warped.

The pressure for hot-pressing the stacked body 1 is preferably 0.1 MPa or more, more preferably 0.5 MPa or more, even more preferably 1 MPa or more. Moreover, the pressure for hot-pressing the stacked body 1 is preferably 10 MPa or less, more preferably 8 MPa or less. When the pressure is 10 MPa or less, the stacked body can be sealed without damaging the semiconductor chips 14 largely.

The period for the hot pressing is preferably 0.3 minute or longer, more preferably 0.5 minute or longer. Moreover, the period for the hot pressing is preferably 10 minutes or shorter, more preferably 5 minutes or shorter.

The hot pressing is conducted preferably in a reduced-pressure atmosphere. The hot pressing in the reduced-pressure atmosphere makes it possible to decrease the voids so that the thermosetting resin sheet can be satisfactorily embedded in the irregularities. About conditions for the reduced pressure, the pressure ranges, for example, from 0.1 to 5 kPa, preferably from 0.1 to 100 Pa.

The sealed body 51 yielded by hot-pressing the stacked body 1 has the semiconductor chips 14 and the thermosetting resin sheet 12 covering the semiconductor chips 14. The sealed body 51 contacts the temporarily-fixing material 11b and the separator 13.

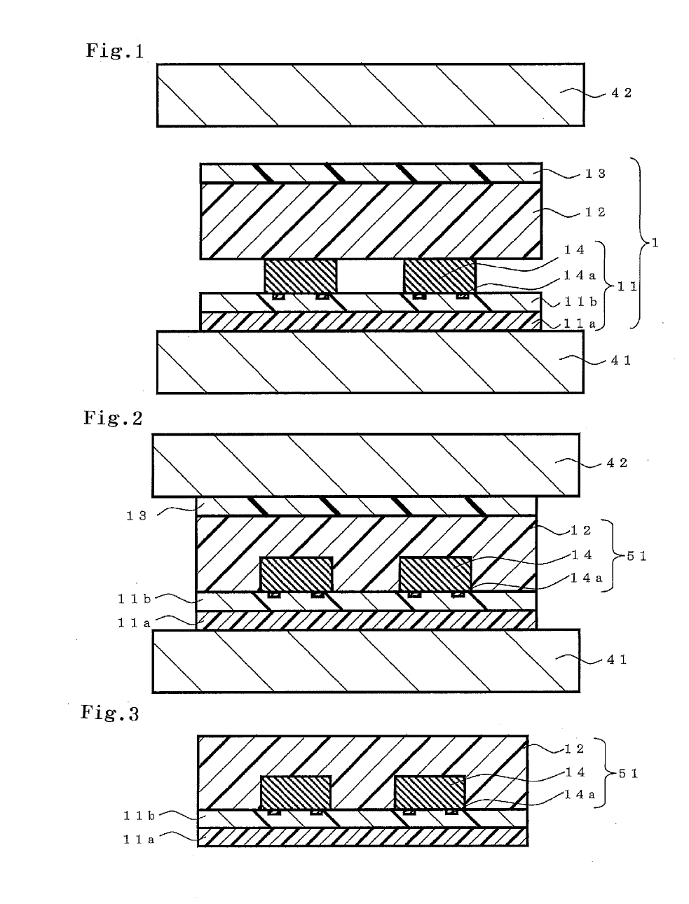

As illustrated in FIG. 3, the separator 13 is peeled off from the sealed body 51.

Next, the sealed body 51 is heated to cure the thermosetting resin sheet 12. In this way, a cured body 52 is formed.

The heating temperature is preferably 100° C. or higher, more preferably 120° C. or higher. In the meantime, the upper limit of the heating temperature is preferably 200° C. or lower, more preferably 180° C. or lower. The heating period is preferably 10 minutes or longer, more preferably 30 minutes or longer. In the meantime, the upper limit of the heating period is preferably 180 minutes or shorter, more preferably 120 minutes or shorter. When the sealed body 51 is heated, the sealed body 51 is preferably pressurized. The pressure is preferably 0.1 MPa or more, more preferably 0.5 MPa or more. In the meantime, the upper limit thereof is preferably 10 MPa or less, more preferably 5 MPa or less.

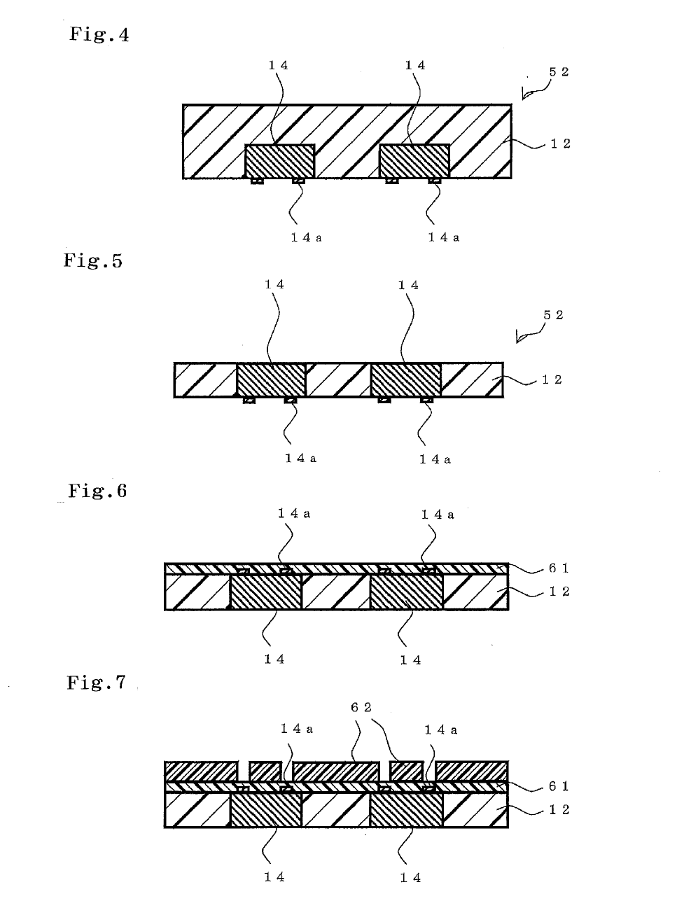

As illustrated in FIG. 4, the temporarily-fixing material 11b is heated to lower the adhesive strength of the temporarily-fixing material 11b, and subsequently the temporarily-fixing material 11b is peeled off from the cured body 52. In this way, the electrode pads 14a are made naked.

As illustrated in FIG. 5, a surface of the cured body 52 that is opposite to the cured-body-52-surface that had contacted the temporarily-fixing material 11b is ground. The method for the grinding is, for example, a grinding method using a grindstone rotatable at a high speed.

As illustrated in FIG. 6, a buffer coat film 61 is formed onto a surface of the cured body 52 that had contacted the temporarily-fixing material 11b. For the buffer coat film 61, for example, a photosensitive polyimide, or a photosensitive polybenzooxazole (PBO) is usable.

As illustrated in FIG. 7, in a state that a mask 62 is arranged on the buffer coat film 61, the workpiece is exposed to light, developed and etched to form openings in the buffer coat film 61. In this way, the electrode pads 14a are made naked.

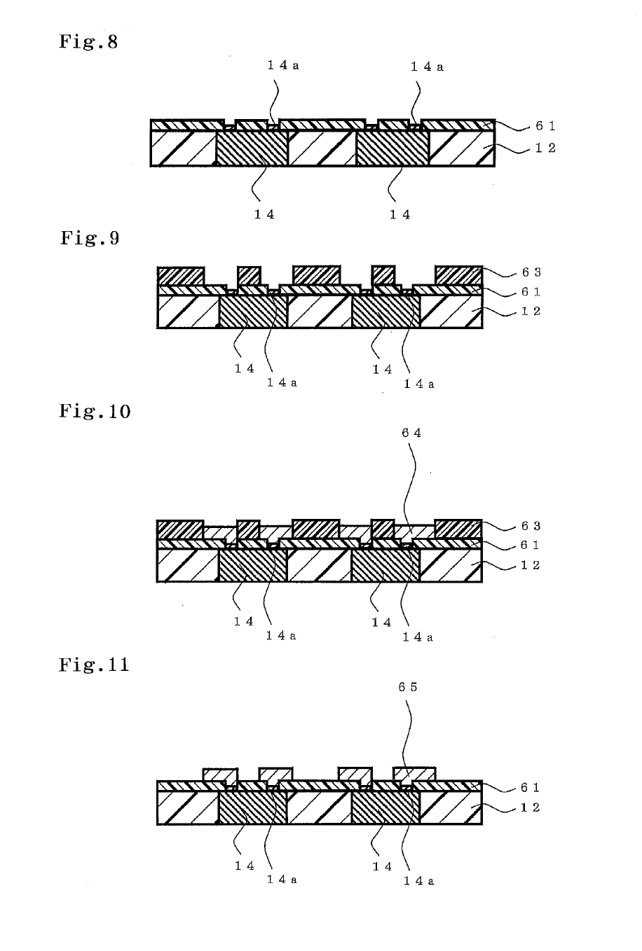

Next, as illustrated in FIG. 8, the mask 62 is removed.

Next, a seed layer is formed onto the buffer coat film 61 and the electrode pads 14a.

As illustrated in FIG. 9, a resist 63 is formed onto the seed layer.

As illustrated in FIG. 10, a plating pattern 64 is formed onto the seed layer by a plating method such as copper electroplating.

As illustrated in FIG. 11, the resist 63 is removed, and then the seed layer is etched to complete re-interconnections 65.

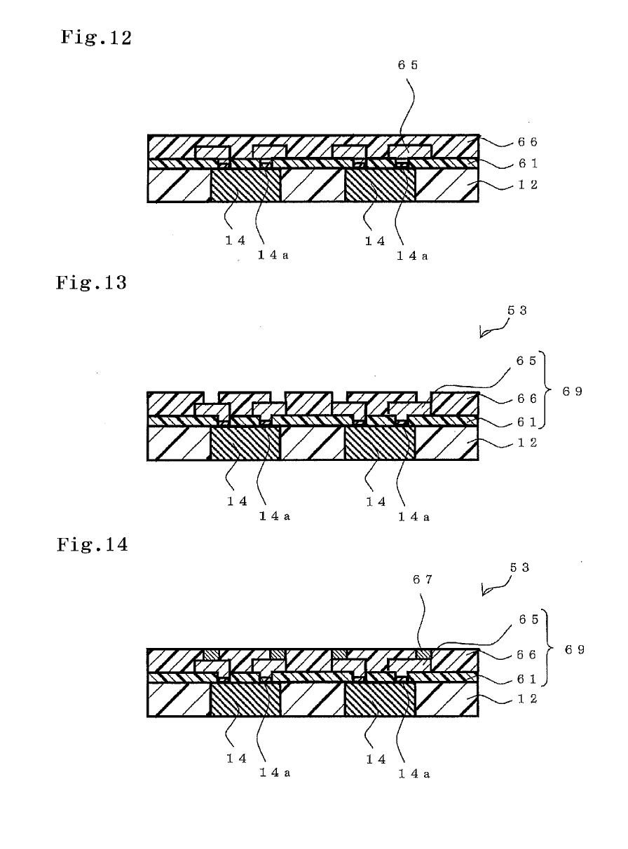

As illustrated in FIG. 12, a protective film 66 is formed onto the re-interconnections 65. For the protective film 66, for example, a photosensitive polyimide or a photosensitive polybenzooxazole (PBO) is usable.

As illustrated in FIG. 13, openings are made in the protective film 66 to make the re-interconnections 65 positioned below the protective film 66 naked. In this way, a re-interconnection layer 69 including the re-interconnections 65 on the cured body 52 is finished to yield a re-interconnection body 53 having the cured body 52 and the re-interconnection layer 69 formed on the cured body 52.

As illustrated in FIG. 14, electrodes (UBM: under bump metal) 67 are formed on the naked re-interconnections 65.

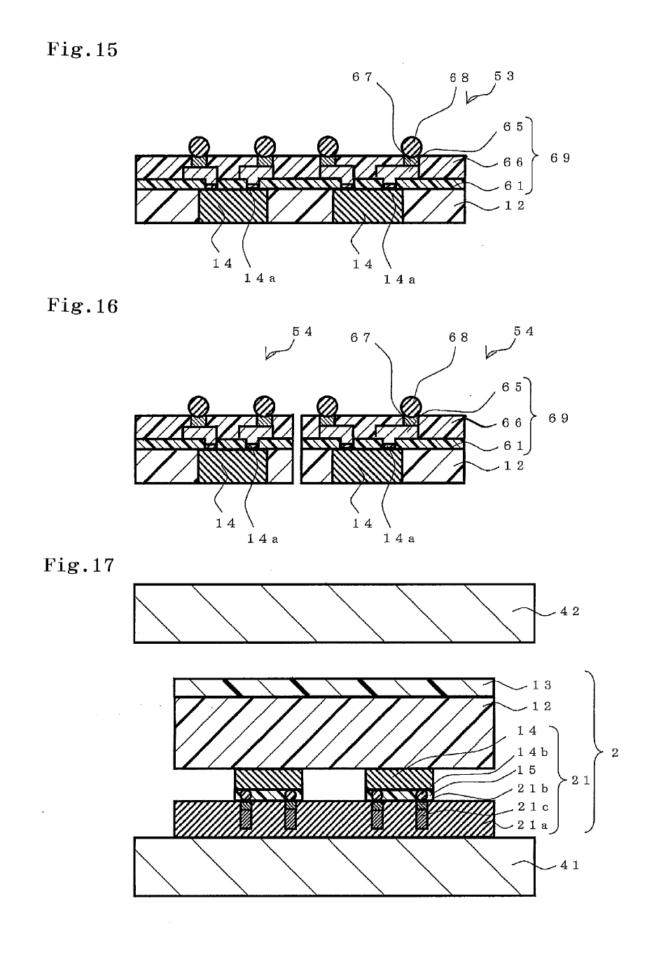

As illustrated in FIG. 15, bumps 68 are formed on the electrodes 67, respectively. The bumps 68 are electrically connected through the electrodes 67 and the re-interconnections 65 to the respective electrode pads 14a.

As illustrated in FIG. 16, the re-interconnection body 53 is divided (or diced) into individual pieces to yield semiconductor packages 54.

The above-mentioned process makes it possible to yield the semiconductor packages 54, in each of which some of the interconnections are led to the outside of a chip region of the package.

### Thermosetting Resin Sheet 12:

The thermosetting resin sheet 12 will be described.

The viscosity of the thermosetting resin sheet 12 at 90° C. is preferably 100000 Pa·s or less, more preferably 50000 Pa·s or less, even more preferably 40000 Pa·s or less. When the viscosity is 100000 Pa·s or less, the thermosetting resin sheet 12 can be satisfactorily embedded in the irregularities. The lower limit of the viscosity of the thermosetting resin sheet 12 at 90° C. is not particularly limited. The viscosity of the thermosetting resin sheet 12 at 90° C. is, for example, 100 Pa·s or more, preferably 500 Pa·s or more, more preferably 1000 Pa·s or more. When the viscosity is 100 Pa·s or more, the generation of voids made from, for example, out gas, can be restrained.

The viscosity at 90° C. is measurable by a method described in the item EXAMPLES.

The thermosetting resin sheet 12 has thermosetting property. The thermosetting resin sheet 12 preferably contains a thermosetting resin such as an epoxy resin or a phenolic resin.

The epoxy resin is not particularly limited, and examples thereof include triphenyl methane type epoxy resin, cresol novolak type epoxy resin, biphenyl type epoxy resin, modified bisphenol A type epoxy resin, bisphenol A type epoxy resin, bisphenol F type epoxy resin, modified bisphenol F type epoxy resin, dicyclopentadiene type epoxy resin, phenol novolak type epoxy resin, phenoxy resin, and other various epoxy resins. These epoxy resins may be used alone or in combination of two or more thereof.

In order to secure reactivity, the epoxy resin is preferably a resin which has an epoxy equivalent of 150 to 250, and has a softening point or melting point of 50 to 130° C. to be solid at room temperature. Out of species of the epoxy resin, more preferred are triphenylmethane type epoxy resin, cresol novolak type epoxy resin, and biphenyl type epoxy resin from the viewpoint of the reliability of the resin sheet. Preferred is bisphenol F type epoxy resin.

The phenolic resin is not particularly limited as long as it initiates a curing reaction with an epoxy resin. Examples thereof include a phenol novolak resin, a phenolaralkyl resin, a biphenylaralkyl resin, a dicyclopentadiene-type phenolic resin, a cresol novolak resin, and a resol resin. These phenolic resins may be used either alone or in combination of two or more thereof.

A phenolic resin having a hydroxyl equivalent of 70 to 250 and a softening point of 50° C. to 110° C. is preferably used from the viewpoint of reactivity with the epoxy resin. Among these phenolic resins, a phenol novolak resin can be preferably used from the viewpoint of its high curing reactivity. Further, a phenolic resin having low moisture absorption such as a phenolaralkyl resin and a biphenylaralkyl resin can also be suitably used from the viewpoint of its reliability.

The total content of the epoxy resin and the phenolic resin in the thermosetting resin sheet 12 is preferably 5% or more by weight. When the total content is 5% or more by weight, the sheet can satisfactorily gain an adhesive strength onto the semiconductor chips 14 and others. The total content of the epoxy resin and the phenolic resin in the thermosetting resin sheet 12 is preferably 40% or less by weight, more preferably 20% or less by weight. When the total content is 40% or less by weight, the sheet 12 can be controlled to be low in hygroscopicity.

From the viewpoint of curing reactivity, the compounding ratio of the epoxy resin to the phenolic resin is preferably set so that the total amount of the hydroxy groups in the phenolic resin is 0.7 equivalent to 1.5 equivalents, and more preferably 0.9 equivalent to 1.2 equivalents per one equivalent of the epoxy groups in the epoxy resin.

The thermosetting resin sheet 12 preferably contains a curing promoter.

The curing promoter is not particularly limited as long as it promotes curing of the epoxy resin and the phenolic resin. Examples thereof include imidazole-based curing promoters such as 2-methylimidazole (trade name; 2MZ), 2-undecylimidazole (trade name; C11-Z), 2-heptadecylimidazole (trade name; C17Z), 1,2-dimethylimidazole (trade name; 1.2DMZ), 2-ethyl-4-methylimidazole (trade name; 2E4MZ), 2-phenylimidazole (trade name; 2PZ), 2-phenyl-4-methylimidazole (trade name; 2P4MZ), 1-benzyl-2-methylimidazole (trade name; 1B2MZ), 1-benzyl-2-phenylimidazole (trade name; 1B2PZ), 1-cyanoethyl-2-methylimidazole (trade name; 2MZ-CN), 1-cyanoethyl-2-undecylimidazole (trade name; C11Z-CN), 1-cyanoethyl-2-phenylimidazolium trimellitate (trade name; 2PZCNS-PW), 2,4-diamino-6-[2′-methylimidazolyl-(1′)]-ethyl-s-triazine (trade name; 2MZ-A), 2,4-diamino-6-[2′-undecylimidazolyl-(1′)]-ethyl-s-triazine (trade name; C11Z-A), 2,4-diamino-6-[2′-ethyl-4′-methylimidazolyl-(1′)]-ethyl-s-triazine (trade name; 2E4MZ-A), 2,4-diamino-6-[2′-methylimidazolyl-(1′)]-ethyl-s-triazine isocyanuric acid adduct (trade name; 2MA-OK), 2-phenyl-4,5-dihydroxymethylimidazole (trade name; 2PHZ-PW), and 2-phenyl-4-methyl-5-hydroxymethylimidazole (trade name; 2P4MZ-PW) (all of these compounds are manufactured by Shikoku Chemicals Corporation).

Particularly preferred are imidazole curing promoters since the promoters restrain curing reaction at the kneading temperature. More preferred are 2-phenyl-4,5-dihydroxymethylimodazole, and 2,4-diamino-6-[2′-ethyl-4′-methylimidazolyl-(1′)]ethyl-s-triazine; and even more preferred is 2-phenyl-4,5-dihydroxymethylimodazole.

The content of the curing promoter is preferably 0.2 parts or more, more preferably 0.5 parts or more, even more preferably 0.8 parts or more by weight for 100 parts by weight of the total of the epoxy resin and the phenolic resin. The content of the curing promoter is preferably 5 parts or less, more preferably 2 parts or less by weight for 100 parts by weight of the total of the epoxy resin and the phenolic resin.

The thermosetting resin sheet 12 preferably contains a thermoplastic resin (elastomer).

Examples of the thermoplastic resin include natural rubber, butyl rubber, isoprene rubber, chloroprene rubber, an ethylene-vinylacetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6, 6-nylon, a phenoxy resin, an acrylic resin, saturated polyester resins such as PET and PBT, a polyamideimide resin, a fluoro resin, a styrene-isobutylene-styrene triblock copolymer, and a methylmethacrylate-butadiene-styrene copolymer (MBS resin). These thermoplastic resins may be used alone or in combination of two or more thereof.

The content of the thermoplastic resin(s) in the thermosetting resin sheet 12 is preferably 1% or more by weight. When the content is 1% or more by weight, softness and flexibility can be given to the sheet 12. The content of the thermoplastic resin(s) in the thermosetting resin sheet 12 is preferably 30% or less, more preferably 10% or less, even more preferably 5% or less by weight. When the content is 30% or less by weight, the sheet 12 can satisfactorily gain adhering strength to the semiconductor chips 14 and others.

The thermosetting resin sheet 12 preferably contains an inorganic filler. By incorporating the inorganic filler thereinto, the sheet 12 can be decreased in thermal expansion coefficient α.

Examples of the inorganic filler include quartz glass, talc, silica (fused silica, crystalline silica, etc.), alumina, aluminum nitride, silicon nitride, and boron nitride. Among these inorganic fillers, silica and alumina are preferable, and silica is more preferable because the thermal expansion coefficient can be reduced well. Silica is preferably fused silica and more preferably spherical fused silica because of its excellent fluidity.

The average particle diameter of the inorganic filler is preferably 1 μm or more. When the average particle diameter is 1 μm or more, the thermosetting resin sheet 12 easily gains flexibility and softness. The average particle diameter of the inorganic filler is preferably 50 μm or less, more preferably 30 μm or less. When the average particle diameter is 50 μm or less, the inorganic filler is easily filled into the sheet to a high degree.

The average particle diameter can be derived, for example, by using a sample extracted at will from a population thereof, and measuring the sample by use of a laser diffraction scattering type particle size distribution measuring instrument.

The inorganic filler is preferably treated (pretreated) with a silane coupling agent. By this treatment, wettability of the inorganic filler to the resin can be improved, and dispersibility of the inorganic filler can be enhanced.

The silane coupling agent is a compound having a hydrolyzable group and an organic functional group in a molecule.

Examples of the hydrolyzable group include alkoxy groups having 1 to 6 carbon atoms such as a methoxy group and an ethoxy group, an acetoxy group, and a 2-mthoxyrthoxy group. Among these, a methoxy group is preferable because it is easy to remove a volatile component such as an alcohol generated by hydrolysis.

Examples of the organic functional group include a vinyl group, an epoxy group, a styryl group, a methacrylic group, an acrylic group, an amino group, a ureido group, a mercapto group, a sulfide group, an isocyanate group. Among these, an epoxy group is preferable because the epoxy group can easily react with an epoxy resin and a phenolic resin.

Examples of the silane coupling agent include vinyl group-containing silane coupling agents such as vinyltrimethoxysilane and vinyltriethoxysilane; epoxy group-containing silane coupling agents such as 2-(3,4-epoxycyclohexyl)ethyltrimethoxysilane and 3-glycidoxypropyl methyldimethoxysilane, 3-glycidoxypropyl trimethoxysilane, 3-glycidoxypropyl methyldiethoxysilane, and 3-glycidoxypropyl triethoxysilane; styryl group-containing silane coupling agents such as p-styryltrimethoxysilane; methacrylic group-containing silane coupling agents such as 3-methacryloxypropylmethyldimethoxysilane, 3-methacryloxypropyltrimethoxysilane, 3-methacryloxypropylmethyldiethoxysilane, and 3-methacryloxypropyltriethoxysilane; acrylic group-containing silane coupling agents such as 3-acryloxypropyltrimethoxysilane; amino group-containing silane coupling agents such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, and N-(vinylbenzyl)-2-aminoethyl-3-aminopropyltrimethoxysilane; ureido group-containing silane coupling agents such as 3-ureidopropyltriethoxysilane; mercapto group-containing silane coupling agents such as 3-mercaptopropylmethyldimethoxysilane and 3-mercaptopropyltrimethoxysilane; sulfide group-containing silane coupling agents such as bis(triethoxysilylpropyl)tetrasulfide; and isocyanate group-containing silane coupling agents such as 3-isocyanatepropyltriethoxysilane.

A method of treating the inorganic filler with the silane coupling agent is not especially limited, and examples thereof include a wet method of mixing the inorganic filler and the silane coupling agent in a solvent and a dry method of treating the inorganic filler with the silane coupling agent in a gas phase.

The amount of the silane coupling agent to be used for the treatment is not especially limited; however, 0.1 to 1 part by weight of the silane coupling agent is preferably used for the treatment to 100 parts by weight of the non-treated inorganic filler.

The content of the inorganic filler in the thermosetting resin sheet 12 is preferably 20% or more, more preferably 70% or more, even more preferably 74% or more by volume. In the meantime, the content of the inorganic filler is preferably 90% or less, more preferably 85% or less by volume. When the content is 90% or less by volume, the sheet 12 can gain a good irregularity-following performance.

The content of the inorganic filler can be described by using “% by weight” as a unit. As a typical example, the content of silica is described by using “% by weight” as a unit.

The specific gravity of silica is normally 2.2 g/cm³. Therefore, a preferred range of the content (% by weight) of silica is as follows.

The content of silica in the thermosetting resin sheet 12 is preferably 81% by weight or more, and more preferably 84% by weight or more. The content of silica in the thermosetting resin sheet 12 is preferably 94% by weight or less, and more preferably 91% by weight or less.

The specific gravity of alumina is normally 3.9 g/cm³. Therefore, a preferred range of the content (% by weight) of alumina is as follows.

The content of alumina in the thermosetting resin sheet 12 is preferably 88% by weight or more, and more preferably 90% by weight or more. The content of alumina in the thermosetting resin sheet 12 is preferably 97% by weight or less, and more preferably 95% by weight or less.

Besides the components described above, the thermosetting resin sheet 12 may contain, as needed, other compounding agents generally used in manufacture of a sealing resin, such as a flame retardant component, a pigment, and a silane coupling agent.

Examples of the flame retardant component include various types of metal hydroxides such as aluminum hydroxide, magnesium hydroxide, iron hydroxide, calcium hydroxide, tin hydroxide, and complex metal hydroxides; and a phosphazene compound. Among these flame retardant components, a phosphazene compound is preferable because of its excellent flame retardancy and strength after curing.

The pigment is not particularly limited, and an example thereof is carbon black.

The method for producing the thermosetting resin sheet 12 is not particularly limited, and is preferably a method of kneading the above-mentioned individual components (for example, the epoxy resin, phenolic resin, inorganic filler and curing promoter) to yield a kneaded product, and working the product plastically into a sheet form. This method makes it possible to fill the inorganic filler highly and design the thermal expansion coefficient of the sheet 12 to a low value.

Specifically, the epoxy resin, the phenolic resin, the inorganic filler, the curing promoter, etc. are melted and kneaded using a known kneader such as a mixing roll, a pressurizing kneader, and an extruder to prepare a kneaded product, and the obtained kneaded product is subjected to plastic working to form a sheet. As kneading conditions, the upper limit of the temperature is preferably 140° C. or lower, and more preferably 130° C. or lower. The lower limit of the temperature is preferably higher than or equal to the softening point of components described above, and is 30° C. or higher, and preferably 50° C. or higher, for example. The kneading time is preferably 1 to 30 minutes. The kneading is preferably performed under a reduced pressure condition (under a reduced pressure atmosphere), and the pressure under the reduced pressure condition is 1×10⁴ to 0.1 kg/cm², for example.

It is preferred to apply the plastic working to the kneaded product after the melt kneading in the state that the kneaded product keeps a high temperature without being cooled. The method for the plastic working is not particularly limited, and examples thereof include flat plate pressing, T-die extrusion, screw die extrusion, rolling, roll kneading, inflation extrusion, co-extrusion, and calendering methods. The plastic working temperature is preferably not lower than the respective softening points of the above-mentioned individual components, and is, for example, from 40 to 150° C., preferably from 50 to 140° C., more preferably from 70 to 120° C., considering the thermosetting property and the moldability of the epoxy resin.

It is also preferred to produce the thermosetting resin sheet 12 in an applying or coating manner. The thermosetting resin sheet 12 can be produced, for example, by producing an adhesive composition solution containing the above-mentioned individual components, applying the adhesive composition solution into a predetermined thickness onto a substrate separator to form a coating film, and then drying the coating film.

A solvent used for the adhesive composition solution is not particularly limited, and is preferably an organic solvent in which the individual components can be evenly dispersed, kneaded or dispersed. Examples thereof include dimethylformamide, dimethylacetoamide, N-methylpyrrolidone, ketone solvents such as acetone, methyl ethyl ketone and cyclohexanone, toluene, and xylene.

The substrate separator may be polyethylene terephthalate (PET), polyethylene or polypropylene, or a film or paper piece having a surface coated with a peeling agent such as a fluorine-containing peeling agent or a long-chain alkyl acrylate peeling agent. The method for applying the adhesive composition solution is, for example, roll coating, screen coating or gravure coating. Conditions for drying the coating film are not particularly limited, and are, for example, as follows: a drying temperature of 70 to 160° C. and a drying period of 1 to 5 minutes.

The thickness of the thermosetting resin sheet 12 is not particularly limited; however, it is preferably 100 μm or more, and more preferably 150 μm or more. The thickness of the thermosetting resin sheet 12 is preferably 2,000 μm or less, and more preferably 1,000 μm or less. If the thickness is within the above-described range, the semiconductor chip 14 can be sealed well.

As described above, the production method of Embodiment 1 for the semiconductor packages 54 includes: the step of form the sealed body 51 having the semiconductor chips 14 and the thermosetting resin sheet 12 covering the semiconductor chips 14 by pressurizing the stacked body 1 which includes: the chip temporarily-fixed body 11 having the supporting plate 11a, the temporarily-fixing material 11b stacked on the supporting plate 11a and the semiconductor chips 14 fixed temporarily on the temporarily-fixing material 11b; the thermosetting resin sheet 12 arranged on the chip temporarily-fixed body 11; and the separator 13 which has a tensile storage elastic modulus of 200 MPa or less at 90° C. and is arranged on the thermosetting resin sheet 12.

The method of Embodiment 1 further includes, for example, a step of peeling off the separator 13 from the sealed body 51.

The method of Embodiment 1 further includes, for example, a step of forming the cured body 52, in which the thermosetting resin sheet 12 is cured, by heating the sealed body 51.

The method of Embodiment 1 further includes, for example, a step of peeling off the temporarily-fixing material 11b from the cured body 52.

The method of Embodiment 1 further includes, for example, a step of forming the re-interconnection body 53 by forming the re-interconnection layer 69 onto the surface of the cured body 52 that had contacted the temporarily-fixing material 11b.

The method of Embodiment 1 further includes, for example, a step of yielding the semiconductor packages 54 by dividing the re-interconnection body 53 into individual pieces.

In the method of Embodiment 1, the separator 13 is used, which is low in tensile storage elastic modulus at 90° C. The use makes it possible to deform the separator 13 in conformity with the deformation of the thermosetting resin sheet 12 so that the sheet 12 can be satisfactorily embedded in the irregularities.

In the method of Embodiment 1, pressure is applied across the separator 13 to the thermosetting resin sheet 12 and the others in a parallel-flat-plate manner. Thus, the thermosetting resin sheet 12 can be prevented from adhering to, for example, the lower heating plate 41 and the upper heating plate 42.

### Embodiment 2

As illustrated in FIG. 17, a stacked structure body 2 has a chip mounted wafer 21, a thermosetting resin sheet 12 arranged on the chip mounted wafer 21, and a separator 13 arranged on the thermosetting resin sheet 12. The stacked structure body 2 is located between a lower heating plate 41 and an upper heating plate 42.

The chip mounted wafer 21 has a semiconductor wafer 21a, and semiconductor chips 14 flip-chip-mounted (flip-chip-bonded) onto the semiconductor wafer 21a.

The semiconductor chips 14 each have a circuit-formed surface (active surface). Bumps 14b are arranged on the circuit-formed surface of the semiconductor chip 14.

The semiconductor wafer 21a has a circuit-formed surface. The circuit-formed surface of the semiconductor wafer 21a includes electrodes 21b. The semiconductor wafer 21a also has through electrodes 21c extending along the thickness direction of the semiconductor wafer 21a. The through electrodes 21c are each electrically connected to one of the electrodes 21b.

Each of the semiconductor chips 14 is electrically connected to the semiconductor wafer 21a through some of the bumps 14b and some of the electrodes 21b. An under fill material 15 is filled into between the semiconductor chips 14 and the semiconductor wafer 21a.

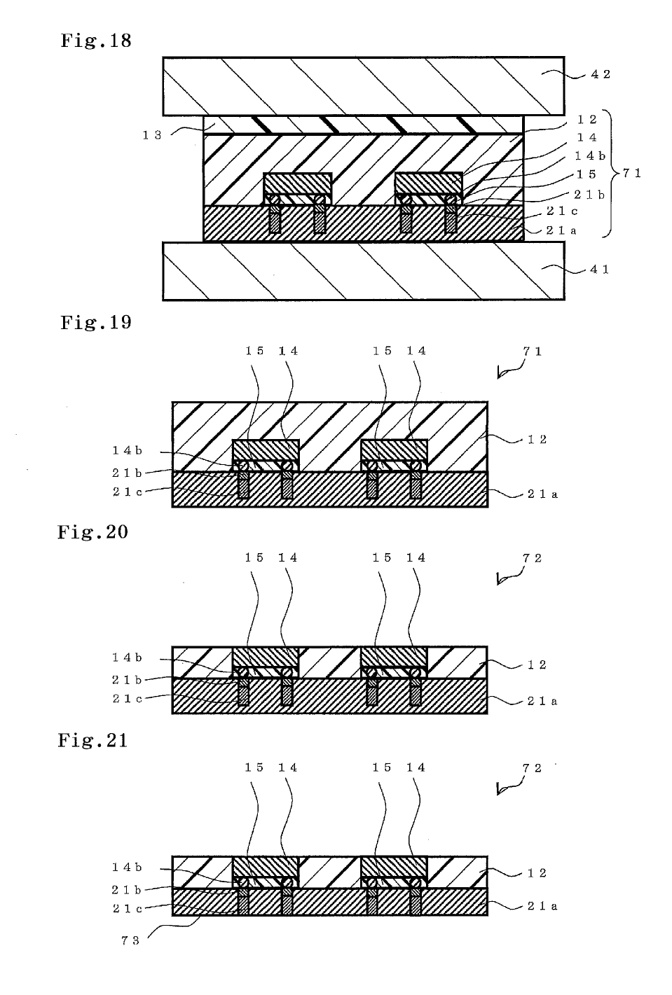

As illustrated in FIG. 18, the lower heating plate 41 and the upper heating plate 42 are used to hot-press the stacked structure body 2 in a parallel-flat-plate manner to form a sealed structure body 71. Preferred conditions for the hot pressing are the same as described in Embodiment 1. The hot pressing is performed preferably in a reduced-pressure atmosphere. Preferred conditions for the reduced-pressure are the same as described in Embodiment 1.

The sealed structure body 71 yielded by hot-pressing the stacked structure body 2 has the semiconductor wafer 21a, the semiconductor chips 14 flip-chip-mounted on the semiconductor wafer 21a, and the thermosetting resin sheet 12 covering the semiconductor chips 14. The sealed structure body 71 has a semiconductor-wafer-21a-arranged surface (wafer surface) and a surface opposite to the wafer surface (opposite surface). The opposite surface contacts the separator 13.

As illustrated in FIG. 19, the separator 13 is peeled off from the sealed structure body 71.

Next, the sealed structure body 71 is heated to cure the thermosetting resin sheet 12 to forma cured structure body 72. Preferred conditions for the heating are the same as described in Embodiment 1.

As illustrated in FIG. 20, the opposite surface of the cured structure body 72 is ground.

As illustrated in FIG. 21, the wafer surface of the cured structure body 72 is ground to make the through electrodes 21c naked. In other words, the through electrodes 21c are naked from a ground surface 73 obtained by grinding the wafer surface.

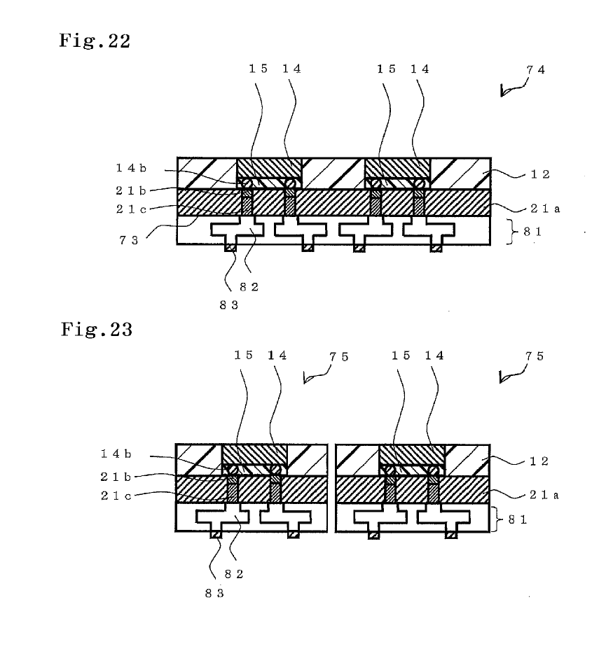

As illustrated in FIG. 22, a semi additive method or some other method is used to form a re-interconnection layer 81 on the ground surface 73 to form a re-interconnection structure body 74. The re-interconnection layer 81 has re-interconnections 82. Next, bumps 83 are formed on the re-interconnection layer 81. The bumps 83 are each electrically connected to a bump 14b of one of the semiconductor chips 14 through one of the re-interconnections 82, one of the electrodes 21b and one of the through electrodes 21c.

As illustrated in FIG. 23, the re-interconnection structure body 74 is divided (diced) into individual pieces. In this process, semiconductor packages 75 are yielded.

### Modified Example 1:

In Embodiment 2, about the chip mounted wafer 21, the under fill material 15 is filled into between the semiconductor chips 14 and the semiconductor wafer 21a. However, in Modified Example 1, the under fill material 15 is not filled into between the semiconductor chips 14 and the semiconductor wafer 21a.

As described above, the production method of Embodiment 2 for the semiconductor packages 75 includes: the step of forming the sealed structure body 71 having the semiconductor wafer 21a, the semiconductor chips 14 mounted on the semiconductor wafer 21a, and the thermosetting resin sheet 12 covering the semiconductor chips 14 by pressurizing the stacked structure body 2 which includes: the chip mounted wafer 21 having the semiconductor wafer 21a and the semiconductor chips 14 mounted on the semiconductor wafer 21a; the thermosetting resin sheet 12 arranged on the chip mounted wafer 21; and the separator 13 which has a tensile storage elastic modulus of 200 MPa or less at 90° C. and is arranged on the thermosetting resin sheet 12.

The method of Embodiment 2 further includes, for example, a step of peeling off the separator 13 from the sealed structure body 71.

The method of Embodiment 2 further includes, for example, a step of forming the cured structure body 72, in which the thermosetting resin sheet 12 is cured, by heating the sealed structure body 71.

The method of Embodiment 2 further includes, for example, a step of forming the cured structure body 72, in which the thermosetting resin sheet 12 is cured, by grinding the semiconductor-wafer-21a-arranged surface of the cured structure body 72.

The method of Embodiment 2 further includes, for example, a step of forming the re-interconnection structure body 74 by forming the re-interconnection layer 81 onto the ground surface 73.

The method of Embodiment 2 further includes, for example, a step of dividing the re-interconnection structure body 74 into individual pieces. In this way, the semiconductor packages 75 are yielded.

In the method of Embodiment 2, the separator 13 is used, which is low in tensile storage elastic modulus at 90° C. This use makes it possible to deform the separator 13 in conformity with the deformation of the thermosetting resin sheet 12, so that the sheet 12 can be satisfactorily embedded in the irregularities.

In the method of Embodiment 2, pressure is applied across the separator 13 to the thermosetting resin sheet 12 and the others in a parallel-flat-plate manner. Thus, the thermosetting resin sheet 12 can be prevented from adhering to, for example, the lower heating plate 41 and the upper heating plate 41.

### Embodiment 3

In a method of Embodiment 3, semiconductor packages are produced, using a vacuum heating joint apparatus (vacuum thermal pressurizing apparatus) described in JP-A-2013-52424, and others.

The vacuum heating joint apparatus will be initially described.

### Vacuum Heating Joint Apparatus:

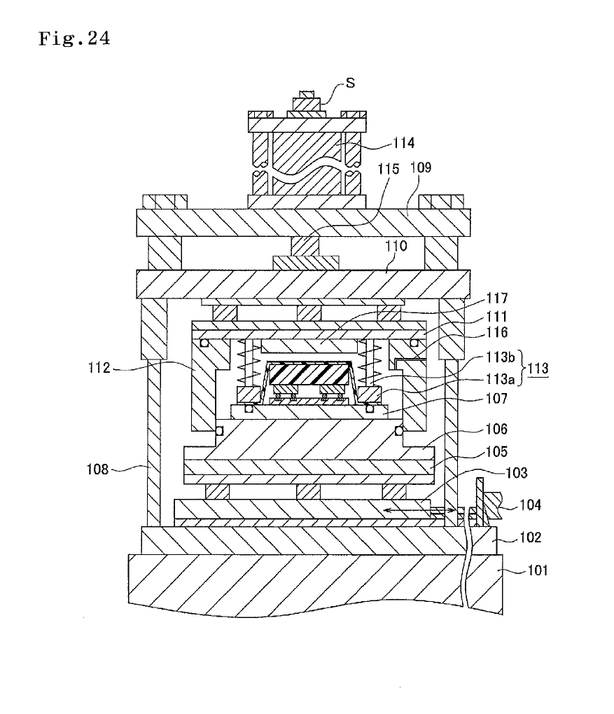

As illustrated in FIG. 24, in the vacuum heating joint apparatus, a pressurizing cylinder lower plate 102 is arranged on a base 101, and a slide shifting table 103 is arranged on the pressurizing cylinder lower plate 102 to be shiftable inside and outside the vacuum heating joint apparatus by a slide cylinder 104. Over the slide shifting table 103, a lower heater plate 105 is arranged adiabatically to this table. A lower plate member 106 is arranged on the upper surface of the lower heater plate 105. A substrate putting stand 107 is put on the upper surface of the lower plate member 106.

Plural columns 108 are located on the pressurizing cylinder lower plate 102 to stand. A pressurizing cylinder upper plate 109 is fixed to the upper ends of the columns 108. The columns 108 may be located directly on the base 101 to stand. Under the pressurizing cylinder upper plate 109, an intermediate shifting member (intermediate member) 110 is arranged in such a manner that the columns 108 are passed into the member 110. An upper heater plate 111 is fixed across a heat insulating plate to the bottom of the intermediate shifting member 110. An upper frame member 112 is airtightly fixed to an outer circumferential region of a lower surface of the upper heater plate 111 to be extended downward. Moreover, an inner frame body 113 is fixed to the lower surface of the upper heater plate 111 inside the upper frame member 112. The upper heater plate 111 functions mainly as a heater for softening the above-mentioned separator 13 and thermosetting resin sheet 12. The lower heater plate 105 functions mainly as a substrate-31a-preheating heater. Furthermore, a flat plate 117 is fixed to the lower surface of the upper heater plate 111 inside the inner frame body 113.

The inner frame body 113 has a frame-form pushing region 113a and rods 113b extended upward from the region 113a. A spring is located around each of rods 113b. The rod 113b is adiabatically fixed to the lower surface of the upper heater plate 111. The frame-form pushing member 113a is urged downward to the rods 113b through the springs to be shiftable upward, so as to buffer an impact generated when the frame-form pushing member 113a is brought into contact with the substrate putting stand 107. The frame-form pushing region 113a at the lower end of the inner frame body 113 is formed to keep the separator 13 airtight between this region 113a and the substrate putting stand 107.

A pressurizing cylinder 114 is arranged on the upper surface of the pressurizing cylinder upper plate 109, and a cylinder rod 115 of the pressurizing cylinder 114 is passed through the pressurizing cylinder upper plate 109 to be fixed to the upper surface of the intermediate shifting member 110. The pressurizing cylinder 114 makes it possible to shift the intermediate shifting member 110, the upper heater plate 111 and the upper frame member 112 in an integral state upward and downward. In FIG. 1, S represents a stopper for regulating a downward shift of the intermediate shifting member 110, the upper heater plate 111 and the upper frame member 112 by the pressurizing cylinder 114. The stopper S is lowered to contact a stopper plate of the upper surface of a main body of the pressurizing cylinder 114. The pressurizing cylinder 114 may be, for example, a hydraulic cylinder, a pneumatic cylinder or a servo cylinder.

From the state that the pressurizing cylinder 114 pulls up the upper frame member 112, the upper frame member 112 is lowered so that the lower end of the upper frame member 112 is airtightly slid onto a step region located at an outer circumstantial region end of the lower plate member 106. At the step region, the pressurizing cylinder 114 is once stopped. In this state, the upper heater plate 111, the upper frame member 112 and the lower plate member 106 form vacuum partition walls, and inside the walls a vacuum chamber is formed. A vacuum/pressurizing port 116 is made into the upper frame member 112 to subject the vacuum chamber to vacuum drawing and apply pressure into this chamber.

In the state that the vacuum chamber is opened, the slide cylinder 104 makes it possible to pull, to the outside, the slide shifting table 103, the lower heater plate 105 and the lower plate member 106 in an integral state. In the state that these members are pulled out, for example, a stacked product 3 can be placed onto the substrate putting stand 107.

The following will describe a sealing method.

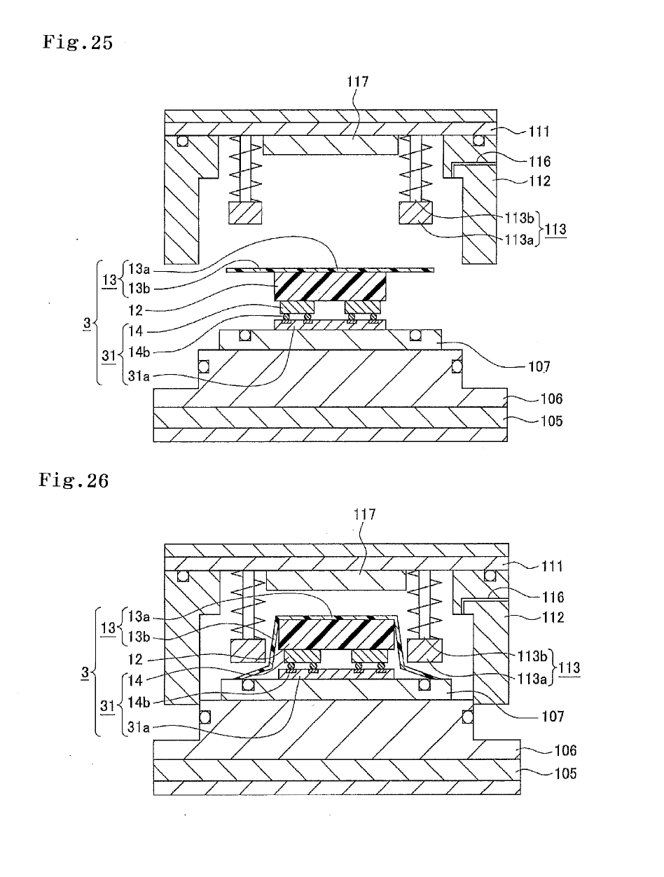

As illustrated in FIG. 25, the stacked product 3 has a chip mounted substrate 31, a thermosetting resin sheet 12 arranged on the chip mounted substrate 31, and a separator 13 arranged on the thermosetting resin sheet 12. The stacked product 3 is placed on the substrate putting stand 107.

The chip mounted substrate 31 has a substrate 31a, and semiconductor chips 14 flip-chip-mounted onto the substrate 31a. Each of the semiconductor chips 14 is electrically connected to the substrate 31a through bumps 14b.

The separator 13 has a central region 13a located on the thermosetting resin sheet 12, and a peripheral region 13b outside the central region 13a. The outer shape dimension of the separator 13 is a size permitting the separator 13 to cover the chip mounted substrate 31 and the thermosetting resin sheet 12.

The outer shape dimension of the thermosetting resin sheet 12 is a size permitting the sheet 12 to seal the semiconductor chips 14. Specifically, the outer shape dimension of the thermosetting resin sheet 12 is the following size when the outer circumferential region of the separator 13 is airtightly held between the upper surface of the substrate putting stand 107 and the lower surface of the inner frame member 13a: a size which does not permit the thermosetting resin sheet 12 to be sandwiched between the upper surface of the substrate putting stand 107 and the lower surface of the inner flame member 13a, and which is necessary for sealing the semiconductor chips 14.

### Chamber Forming Step:

As illustrated in FIG. 26, the upper heater plate 111 and the upper frame member 112 are lowered by the pressurizing cylinder 114 to slide the lower end of the upper frame member 112 airtightly onto a step of the outer edge region of the lower plate member 106. In this way, a chamber is formed which is airtightly surrounded by the upper heater plate 111, the upper frame member 112 and the lower plate member 106. At the stage of forming the chamber, the lowering of the upper heater plate 111 and the upper frame member 112 is stopped.

### Vacuum Drawing Step:

Next, the chamber is subjected to vacuum drawing to make the inside of the chamber into a reduced pressure state (for example, 500 Pa or less).

After the vacuum drawing, the stacked product 3 is heated to soften the thermosetting resin sheet 12 and the separator 13. Examples of the method for heating the stacked product 3 include a method of raising the respective temperatures of the upper heater plate 111 and the lower heater plate 105, a method of raising the temperature of the upper heater plate 111, and a method of raising the temperature of the lower heater plate 105. The heating temperature is preferably equivalent to the hot pressing temperature described in Embodiment 1.

In FIG. 26 is illustrated a situation that the outer circumferential region of the separator 13 contacts the substrate putting stand 107 surface.

### Airtightly Closed Space Forming Step:

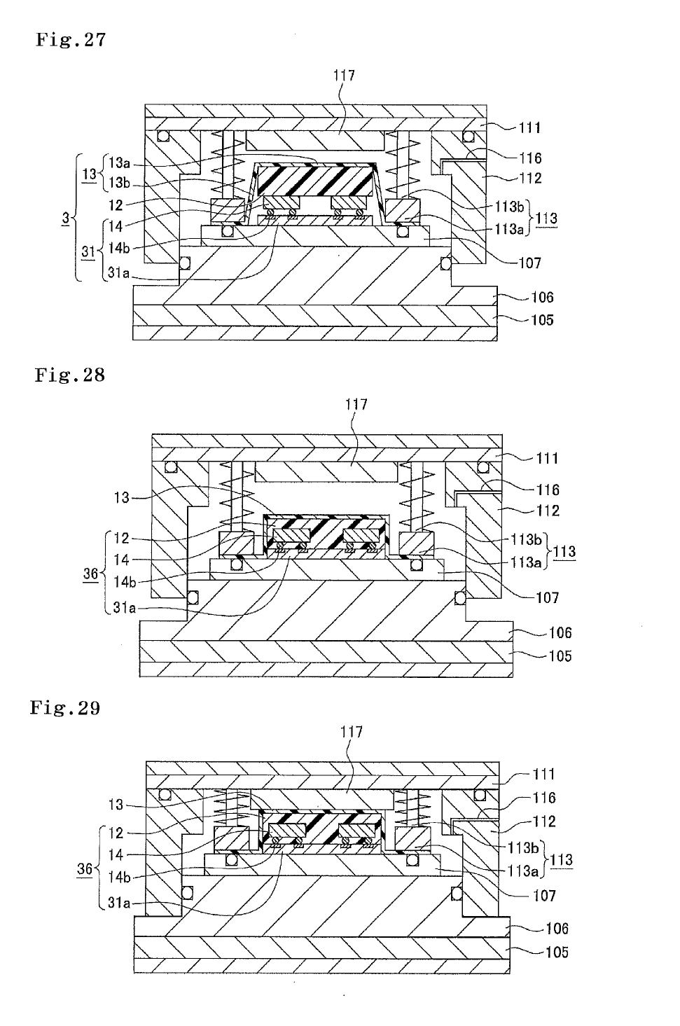

As illustrated in FIG. 27, the inner frame body 113 is lowered to push the outer circumferential region of the separator 13 by the lower surface of the lower end of the inner frame body 113 to cover the chip mounted substrate 31 and the thermosetting resin sheet 12 with the separator 13. In this way, an airtightly closed space is formed for holding the chip mounted substrate 31 and the thermosetting resin sheet 12. The airtightly closed space is airtightly closed by the separator 13. The inside and the outside of the airtightly closed space are in a reduced pressure state since the airtightly closed space is formed after the inside of the vacuum chamber is made into the reduced pressure state.

### Sealing Step:

As illustrated in FIG. 28, a gas is introduced through the vacuum/pressuring port 116 into the chamber to make the outside of the airtightly closed space higher in pressure than the inside of this space. By effect of a difference in pressure between the inside and outside of the airtightly closed space, the semiconductor chips 14 are covered with the thermosetting resin sheet 12 to forma sealed product 36. The sealed product 36 has the substrate 31a, the semiconductor chips 14 mounted on the substrate 31a, and the thermosetting resin sheet 12 covering the semiconductor chips 14. The sealed product 36 has a surface on which the thermosetting resin sheet 12 is arranged. The surface on which the thermosetting resin sheet 12 is arranged contacts the separator 13.

The gas is not particularly limited. Examples thereof include air and nitrogen. The pressure of the gas is not particularly limited, and is preferably the atmospheric pressure or more. The introduction of the gas makes the pressure in the outside of the airtightly closed space equal to or higher than the atmospheric pressure.

As illustrated in FIG. 29, after the gas introduction, the flat plate 117 is lowered to pressurize the sealed product 36 across the separator 13 to flatten the sealed product 36. This manner makes it possible to make the thickness of the sealed product 36 even. The pressurizing pressure is preferably from 0.5 to 20 kgf/cm².

Next, the separator 13 is taken away from the sealed product 36.

Next, the sealed product 36 is heated to cure the thermosetting resin sheet 12 to form a cured product. Conditions for the heating are preferably the same as described in Embodiment 1.

The cured product is made (or diced) into individual pieces to yield semiconductor packages.

### Modified Example 1:

In Embodiment 3, after the vacuum drawing, the stacked product 3 is heated. However, in Modified Example 1, the stacked product 3 is heated before or during the vacuum drawing.

### Modified Example 2:

In Embodiment 3, about the chip mounted substrate 31, no under fill material is filled into between the semiconductor chips 14 and the substrate 31a. However, in Modified Example 2, an under fill material is filled into between the semiconductor chips 14 and the substrate 31a.

### Modified Example 3:

In Embodiment 3, the sealed product 36 is flattened by the flat plate 117. However, in Modified Example 3, the sealed product 36 is not flattened by the flat plate 117.

As described above, the semiconductor package production method of Embodiment 3 includes: the step of forming the sealed product 36 including the substrate 31a, the semiconductor chips 14 mounted on the substrate 31a, and the thermosetting resin sheet 12 covering the semiconductor chips 14 by pressurizing the stacked product 3 which includes: the chip mounted substrate 31 including the substrate 31a and the semiconductor chips 14 mounted on the substrate 31a; the thermosetting resin sheet 12 arranged on the chip mounted substrate 31; and the separator 13, which has a tensile storage elastic modulus of 200 MPa or less at 90° C. and is arranged on the thermosetting resin sheet 12.

The step of forming the sealed product 36 includes, for example, a step of forming the airtightly closed space which holds the chip mounted substrate 31 and the thermosetting resin sheet 12 and which is airtightly closed by the separator 13 by covering the chip mounted substrate 31 and the thermosetting resin sheet 12 arranged on the chip mounted substrate 31 with the separator 13 having the central region 13a located on the thermosetting resin sheet 12 and the peripheral region 13b outside the central region 13a; and a step of forming the sealed product 36 by making the atmosphere outside the airtightly closed space higher in pressure than the inside of the airtightly closed space to form the sealed product 36.

The method of Embodiment 3 further includes, for example, a step of peeling off the separator 13 from the sealed product 36.

The method of Embodiment 3 further includes, for example, a step of forming a cured product, in which the thermosetting resin sheet 12 is cured, by heating the sealed product 36.

The method of Embodiment 3 further includes, for example, a step of yielding semiconductor packages by making the cured product into individual pieces.

In the method of Embodiment 3, the separator 13 is used, which is low in tensile storage elastic modulus at 90° C. This use makes it possible to deform the separator 13 in conformity with the deformation of the thermosetting resin sheet 12, so that the thermosetting resin sheet 12 can be satisfactorily embedded in the irregularities.

In the method of Embodiment 3, the use of the separator 13 makes it possible to make effective use of the pressure difference between the inside and the outside of the airtightly closed space. Thus, the thermosetting resin sheet 12 is easily filled into the space between the substrate 31a and the thermosetting resin sheet 12.

### Examples

Hereinafter, preferred examples of this invention will be illustratively described in detail. However, about materials, blended amounts and others that are described in the examples, the scope of this invention is not limited only to these described matters unless the specification especially includes a restrictive description thereabout.

### [Separators]

Separators are as follows:

Separator A: X-88BM14, manufactured by Mitsui Chemicals, Inc.

Separator B: ODZ5, manufactured by Okura Industry Co., Ltd.

Separator C: DIAFOIL MRA-50, manufactured by Mitsubishi Polyester Film, Inc.

About the separators, evaluations described below were made. The results are shown in Table 1.

### Tensile Storage Elastic Modulus at 90° C.:

From each of the separators, a rectangular sample (a length of 30 mm×a width of 5 mm) was cut out. About this sample, the tensile storage elastic modulus was measured over temperatures from 25° C. to 150° C., using a dynamic viscoelascity measuring instrument (RSA III, manufactured by Rheometric Scientific Inc.) in a tension measuring mode under conditions that the distance between its chucks was 23 mm and the temperature-raising rate was 10° C./minute. From the measurement result, the tensile storage elastic modulus at 90° C. was gained.

TABLE 1
Separator:

| | | Separator A | Separator B | Separator C |
|---|---|---|---|---|
| Evaluation | Tensile storage | 120 | 38 | 380 |
| | elastic modulus | | | |
| | (MPa) at 90° C. | | | |

### [Resin Sheets]

Resin sheets A and B are as follows:

### Components Used to Produce Resin Sheet A:

Components used to produce a resin sheet A are as follows.

Epoxy resin: YSLV-80XY, manufactured by Nippon Steel Chemical Corp. (bisphenol F type epoxy resin; epoxy equivalent: 200 g/eq., and softening point: 80° C.)

Phenolic resin: MEH-7851-SS, manufactured by Meiwa Plastic Industries, Ltd. (phenol novolak resin having a biphenylaralkyl skeleton; hydroxyl equivalent: 203 g/eq., and softening point: 67° C.)

Curing promoter: 2PHZ-PW, manufactured by Shikoku Chemicals Corp. (2-phenyl-4,5-dihydroxymethylimidazole)

Elastomer: SIBSTAR 072T, manufactured by Kaneka Corp. (styrene-isobutylene-styrene triblock copolymer)

Inorganic filler: FB-9454, manufactured by Denka Co., Ltd. (spherical fused silica powder; average particle diameter: 20 μm)

Silane coupling agent: KBM-403, manufactured by Shin-Etsu Chemical Co., Ltd. (3-glycidoxypropyltrimethoxysilane)

Carbon black: #20, manufactured by Mitsubishi Chemical Corp.

### Production of Resin Sheet A:

In accordance with blend proportions described in Table 2, individual components were blended with each other in a mixer, and then melt-kneaded at 120° C. for 2 minutes in a biaxial kneader. Subsequently, the kneaded product was extruded through a T die to produce a resin sheet A having a thickness of 500 μm.

### Components Used to Produce Resin Sheet B:

Components used to produce a resin sheet B are as follows.

Epoxy resin: KI-3000, manufactured by Tohto Kasei Co., Ltd. (o-cresol novolak type epoxy resin; epoxy equivalent: 200 g/eq)

Epoxy resin: EPIKOTE 828, manufactured by Mitsubishi Chemical Corp. (bisphenol A type epoxy resin; epoxy equivalent: 200 g/eq)

Phenolic resin: MEH-7851-SS, manufactured by Meiwa Plastic Industries, Ltd. (phenol novolak resin having a biphenylaralkyl skeleton; hydroxyl equivalent: 203 g/eq., and softening point: 67° C.)

Curing promoter: 2PHZ-PW, manufactured by Shikoku Chemicals Corp. (2-phenyl-4,5-dihydroxymethylimidazole)

Inorganic filler: FB-9454, manufactured by Denka Co., Ltd. (spherical fused silica powder; average particle diameter: 20 μm)

Carbon black: #20, manufactured by Mitsubishi Chemical Corp.

### Production of Resin Sheet B:

In accordance with blend proportions described in Table 2, the epoxy resins, the phenolic resin, methyl ethyl ketone (MEK) and the inorganic filler were incorporated into a container to give a solid concentration of 95%. A planetary centrifugal mixer (manufactured by Thinky Corp.) was used to stir the blend at 800 rpm for 5 minutes. Thereafter, the curing promoter and the carbon black were added thereto. Next, MEK was added thereto to give a solid concentration of 90%, and the resultant was stirred at 800 rpm for 3 minutes to yield a coating liquid. The coating liquid was applied onto a polyethylene terephthalate film (thickness: 50 μm) subjected to silicone release treatment. The coating liquid was then dried at 120° C. for 3 minutes to produce a sheet having a thickness of 100 μm. A roll laminator was used to bond plural pieces from the sheet to each other to yield a resin sheet B having a thickness of 500 μm.

About the resin sheets A and B, an evaluation described below was made. The results are shown in Table 2.

### Viscosity at 90° C.:

From each of the resin sheets A and B, a circular sample having a diameter of 20 mm and a thickness of 1.0 mm was hollowed out. A viscoelasticity measuring instrument ARES (manufactured by a company, TA Instruments) was used to measure the viscosity thereof over temperatures of 60° C. to 150° C. under the following conditions: a temperature-raising rate of 10° C./minute, a frequency of 0.1 Hz and a strain of 20%. The value of the viscosity was measured at 90° C.

TABLE 2
Resin sheet A:

| | | Resin sheet A |
|---|---|---|
| (parts | YSLV-80XY (Epoxy resin) | 453.3 |
| by | MEH-7851-SS (Phenolic resin) | 479.4 |
| weight | 2PHZ-PW (Curing promoter) | 9.3 |
| | SIBSTAR 072T(Elastomer) | 228 |
| | FB-9454 (Inorganic filler) | 8800 |
| | KBM-403 (Silane coupling agent) | 4.4 |
| | #20 (Carbon black) | 30 |
| Total (parts by weight) | | 10004.4 |
| Evaluation | Viscosity (Pa · s) at 90° C. | 23700 |

Resin sheet B:

| | | Resin sheet B |
|---|---|---|
| Blend | KI-3000 (Epoxy resin) | 146.9 |
| (parts by | EPIKOTE 828 (Epoxy resin) | 145.3 |
| weight) | MEH-7851-SS (Phenolic resin) | 291 |
| | 2PHZ-PW (Curing promoter) | 4.5 |
| | FB-9454 (Inorganic filler) | 2706.2 |
| | #20 (Carbon black) | 9.6 |
| Total (parts by weight) | | 3303.5 |
| Evaluation | Viscosity (Pa · s) at 90° C. | 3730 |

### Production of Cured Bodies:

In each of (Comparative) Examples, a temporarily-fixing pressure-sensitive adhesive sheet (No. 3195V, manufactured by Nitto Denko Corp.) was laminated onto a glass plate (TEMPAX glass) having a size of 300 mm×400 mm×1.4 mm thickness. Next, semiconductor elements each having a size of 6 mm×6 mm×200 μm thickness were arranged at intervals of 9 mm onto the temporarily-fixing pressure-sensitive adhesive sheet. Next, either of the resin sheet species was arranged onto the semiconductor elements. Next, one of the separator species was arranged onto the resin sheet to yield a stacked body. A high-precision vacuum pressurizing apparatus (manufactured by Mikado Technos Co., Ltd.) was used to press the stacked body in a parallel-flat-plate manner at 90° C. and 2.5 MPa to yield a sealed body to which the temporarily-fixing pressure-sensitive adhesive sheet was attached.

The sealed body, to which the temporarily-fixing pressure-sensitive adhesive sheet was attached, was heated at 150° C. for 1 hour to cure the resin region of the sealed body to yield a cured body to which the temporarily-fixing pressure-sensitive adhesive sheet was attached. In order to lower the adhesive strength of the temporarily-fixing pressure-sensitive adhesive sheet, the cured body, to which the temporarily-fixing pressure-sensitive adhesive sheet was attached, was heated at 185° C. for 5 minutes, and then the temporarily-fixing pressure-sensitive adhesive sheet was peeled from the cured body.

### [Evaluation]

About the cured body, an evaluation described below was made. The result is shown in Table 3.

### Packing Property:

The cured body surface (observation surface) that had contacted the temporarily-fixing pressure-sensitive adhesive sheet was observed to calculate out the total area of the observation surface and the area therein that was occupied by voids. The proportion of the area occupied by the voids was calculated out in accordance with an expression described below. When the proportion of the area occupied by the voids was less than 1%, the cured body was determined to be good (◯); or when the proportion was 1% or more, the cured body was determined to be bad (x).

The proportion (%) of the area occupied by the voids=“the area occupied by the voids”/“the total area of the observation surface”×100

TABLE 3
Cured body:

| | | | | | | Comparative | Comparative |
|---|---|---|---|---|---|---|---|
| | | Example 1 | Example 2 | Example 3 | Example 4 | Example 1 | Example 2 |
| Resin sheet species | | A | A | B | B | A | B |
| Separator species | | A | B | A | B | C | C |
| Evaluation | Packing property | ∘ | ∘ | ∘ | ∘ | x | x |
| | (determined) | | | | | | |
| | Proportion (%) of void | 0 | 0 | 0 | 0 | 6 | 2 |
| | area (“void area”/ | | | | | | |
| | “total area” × 100) | | | | | | |

### DESCRIPTION OF REFERENCE SIGNS

1: Stacked body
11: Chip temporarily-fixed body
12: Thermosetting resin sheet
13: Separator
41: Lower heating plate
42: Upper heating plate
11a: Supporting plate
11b: Temporarily-fixing material
14: Semiconductor chip
14a: Electrode pad
51: Sealed body
52: Cured body
61: Buffer coat film
62: Mask
63: Resist
64: Plating pattern
65: Re-interconnection
66: Protective film
67: Electrode
68: Bump
69: Re-interconnection layer
53: Re-interconnection body
54: Semiconductor package
2: Stacked structure body
14b: Bump
21: Chip mounted wafer
21a: Semiconductor wafer
21b: Electrode
21c: Through electrode
15: Under fill material
71: Sealed structure body
72: Cured structure body
73: Ground surface
81: Re-interconnection layer
82: Re-interconnection
83: Bump
74: Re-interconnection structure body
75: Semiconductor package
3: Stacked product
101: Base
102: Pressurizing cylinder lower plate
103: Slide shifting table
104: Slide cylinder
105: Lower heater plate
106: Lower plate member
107: Substrate putting stand
108: Column
109: Pressurizing cylinder upper plate
110: Intermediate shifting member
111: Upper heater plate
112: Upper frame member
113: Inner frame body
113a: Frame-form pushing region
113b: Rod
114: Pressurizing cylinder
115: Cylinder rod
116: Vacuum/pressurizing port
117: Flat plate
31a: Substrate
31: Chip mounted substrate
13a: Central region
13b: Peripheral region
36: Sealed product
S: Stopper

1. A semiconductor package production method comprising:
a step of forming a sealed body by pressurizing a stacked body which comprises: a chip-temporarily-fixed body comprising a supporting plate, a temporarily-fixing material stacked over the supporting plate, and a semiconductor chip fixed temporarily over the temporarily-fixing material; a thermosetting resin sheet arranged over the chip-temporarily-fixed body; and a separator having a tensile storage elastic modulus of 200 MPa or less at 90° C. and arranged over the thermosetting resin sheet,
the sealed body comprising the semiconductor chip and the thermosetting resin sheet covering the semiconductor chip.

2. The semiconductor package production method according to claim 1, wherein in the step of forming the sealed body, the stacked body is pressurized while heated.

3. The semiconductor package production method according to claim 1, wherein in the step of forming the sealed body, the stacked body is pressurized at a temperature of 70° C. to 100° C.

4. The semiconductor package production method according to claim 1, further comprising:
a step of peeling off the separator from the sealed body.

5. The semiconductor package production method according to claim 1, further comprising:
a step of heating the sealed body to form a cured body in which the thermosetting resin sheet is cured, and
a step of peeling off the temporarily-fixing material from the cured body.

6. The semiconductor package production method according to claim 5, further comprising:
a step of forming a re-interconnection body by forming a re-interconnection layer on a surface of the cured body that had contacted the temporarily-fixing material.

7. The semiconductor package production method according to claim 6, further comprising:
a step of making the re-interconnection body into individual pieces to yield semiconductor packages.

8. A semiconductor package production method comprising:
a step of forming a sealed structure body by pressurizing a stacked structure body which comprises: a chip mounted wafer comprising a semiconductor wafer and a semiconductor chip mounted over the semiconductor wafer; a thermosetting resin sheet arranged over the chip mounted wafer; and a separator having a tensile storage elastic modulus of 200 MPa or less at 90° C. and arranged over the thermosetting resin sheet,
the sealed structure body comprising the semiconductor wafer, the semiconductor chip mounted over the semiconductor wafer, and the thermosetting resin sheet covering the semiconductor chip.

9. A semiconductor package production method comprising:
a step of forming a sealed product pressurizing a stacked product which comprises: a chip mounted substrate comprising a substrate and a semiconductor chip mounted over the substrate; a thermosetting resin sheet arranged over the chip mounted substrate; and a separator having a tensile storage elastic modulus of 200 MPa or less at 90° C. and arranged over the thermosetting resin sheet;
the sealed product comprising the substrate, the semiconductor chip mounted over the substrate, and the thermosetting resin sheet covering the semiconductor chip.
